(19) United States
(12) Patent Application Publication
(10) Pub. No.: US 2018/0375307 A1
(43) Pub. Date: Dec. 27, 2018

(54) ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventor: Yukinori Kita, Yokkaichi, Mie (JP)

(21) Appl. No.: 15/775,024

(22) PCT Filed: Dec. 6, 2016
(86) PCT No.: PCT/JP2016/086170

§ 371 Date: May 10, 2018

(30) Foreign Application Priority Data
Dec. 16, 2015 (JP) 2015-245108

(51) Int. Cl. H02G 3/08; B60R 16/023; H05K 1/18; H02G 5/08; H02G 3/03

(52) U.S. Cl. CPC H02G 3/081; B60R 16/0239; H05K 2201/10272; H02G 5/08; H02G 3/03; H05K 1/181

(57) ABSTRACT

An electrical junction box includes: a circuit board having a mounting face on which an electronic component having a main body and a connecting portion is mounted; and a case accommodating the circuit board, wherein the case includes a bonding case part having a bonding face to which a face of the circuit board opposite to the mounting face is bonded, and a pressing case part assembled to the bonding case part and having a pressing portion that presses the main body of the electronic component toward the bonding face.

### CROSS-REFERENCE TO RELATED APPLICATIONS

This application is the U.S. national stage of PCT/JP2016/086170 filed Dec. 6, 2016, which claims priority of Japanese Patent Application No. JP 2015-245108 filed Dec. 16, 2015.

### TECHNICAL FIELD

The technology disclosed in this specification relates to an electrical junction box.

### BACKGROUND

Conventionally, electrical junction boxes are known in which a circuit board with an electronic component mounted thereon is accommodated in a case. In such electrical junction boxes, the circuit board may be fixed to the case using an adhesive.

In production of this sort of electrical junction boxes, first, a conductive circuit is printed through printed wiring on a front face of an insulating substrate, and a plurality of bus bars are arranged in a predetermined pattern on its back face. Next, electronic components are mounted on the front face side, for example, through reflow soldering or the like, and thus a circuit board is formed. Then, for example, an adhesive is applied to a predetermined region of one of two halves obtained by dividing a case, and the circuit board is placed such that its bus bar-side face is laid over the adhesive and pressure is applied to it, and thus the circuit board is bonded to the case. After the adhesive is solidified and the circuit board is fixed, the other of the two halves of the case is assembled to it, completing the electrical junction box.

However, with such a production method, the next operation cannot be started until the adhesive is completely solidified. Thus, after the circuit board is positioned with respect to the case, the circuit board has to be held using a dedicated jig so as not to be dislocated until the adhesive is solidified. Furthermore, since it takes time for an adhesive to be solidified, the operation efficiency is poor.

Furthermore, when fixings a circuit board using an adhesive in this manner, it is necessary to use an adhesive with a high adhesive force such that the adhesive is not peeled off due to vibrations or the like when the vehicle is running. Examples of such an adhesive with a high adhesive force may include thermosetting resins, but thermosetting resins require the circuit board and the case to be integrally held at high temperature and high pressure for a relatively long period of time, and thus dedicated facilities are necessary, which increases the production cost. Furthermore, since the entire assembly is once put at high temperature, there is a problem that the time necessary for cooling is also long.

The technology disclosed in this specification has been completed based on these circumstances, and it is an object thereof to provide an electrical junction box that is excellent in terms of productivity and can be produced at low cost.

### SUMMARY

The technology disclosed in this specification is directed to an electrical junction box including: a circuit board having a mounting face on which an electronic component having a main body and a connecting portion is mounted; and a case accommodating the circuit board, wherein the case includes: a bonding case part having a bonding face to which a face of the circuit board opposite to the mounting face is bonded; and a pressing case part assembled to the bonding case part and having a pressing portion that presses the main body of the electronic component toward the bonding face.

With this configuration, the pressing portion presses the main body of the electronic component toward the bonding face of the bonding case part, and thus even when an adhesive for fixing the circuit board and the bonding case part has not been completely solidified, the circuit board is pressed against the bonding case part by means of the electronic component (main body), and is held in an immovable manner. That is to say, the procedure can advance to the next step or the product can be conveyed without waiting for an adhesive to be completely solidified, and thus the productivity is improved.

Furthermore, with this configuration, also after the adhesive is solidified, the pressing by the pressing portion continues, and thus a high adhesive force as in cases where the circuit board and the bonding case part are fixed to each other only with an adhesive is not required. That is to say, although thermosetting resins and the like have conventionally been used as an adhesive in order to ensure a high adhesive force, the above-described configuration makes it possible to use a relatively inexpensive general-purpose adhesive that is solidified at room temperature, and thus the material cost can be kept low. Moreover, dedicated facilities, jigs for holding until an adhesive is solidified, and the like in the case of using thermosetting resins are no more necessary, and thus the facility cost can be kept low, and the overall production cost can be significantly lowered.

The above-described electrical junction box may have a following configuration.

It is possible that the pressing case part includes a cover that covers the circuit board, and a frame member arranged between the cover and the bonding case part, the frame member is provided with a bridge portion arranged at a position facing at least the main body of the electronic component when the circuit board is positioned on the bonding case part, and the pressing portion projects from the bridge portion toward the circuit board.

If the pressing case part is constituted by the cover and the frame member in this manner, and the pressing portion is integrally formed with the frame member, then the pressing portion can be provided with a simple configuration without increasing the number of parts.

Furthermore, it is possible that the pressing case part and the bonding case part are fixed through screws.

With this configuration, the pressing portion can reliably press the main body of the electronic component toward the bonding face of the bonding case part.

It is possible that the bonding case part is made of metal. With this configuration, heat generated by the circuit board is efficiently absorbed by the bonding case part and dissipated to the outside, and thus the temperature of the electrical junction box can be prevented from being high.

Moreover, it is possible that a bus bar is arranged on a face of the circuit board opposite to the mounting face.

### ADVANTAGEOUS EFFECTS OF INVENTION

The technology disclosed in this specification can provide an electrical junction box that is excellent in terms of productivity and can be produced at low cost.

### BRIEF DESCRIPTION OF DRAWINGS

FIG. 1 is a perspective view of an electrical junction box according to an embodiment.

FIG. 2 is an exploded perspective view of a heat dissipation plate to which a circuit assembly is bonded, and a frame.

FIG. 3 is a plan view showing a state in which the frame is assembled to the heat dissipation plate to which the circuit assembly is bonded.

FIG. 4 is a cross-sectional view taken along A-A of FIG. 3.

### DETAILED DESCRIPTION OF PREFERRED EMBODIMENTS

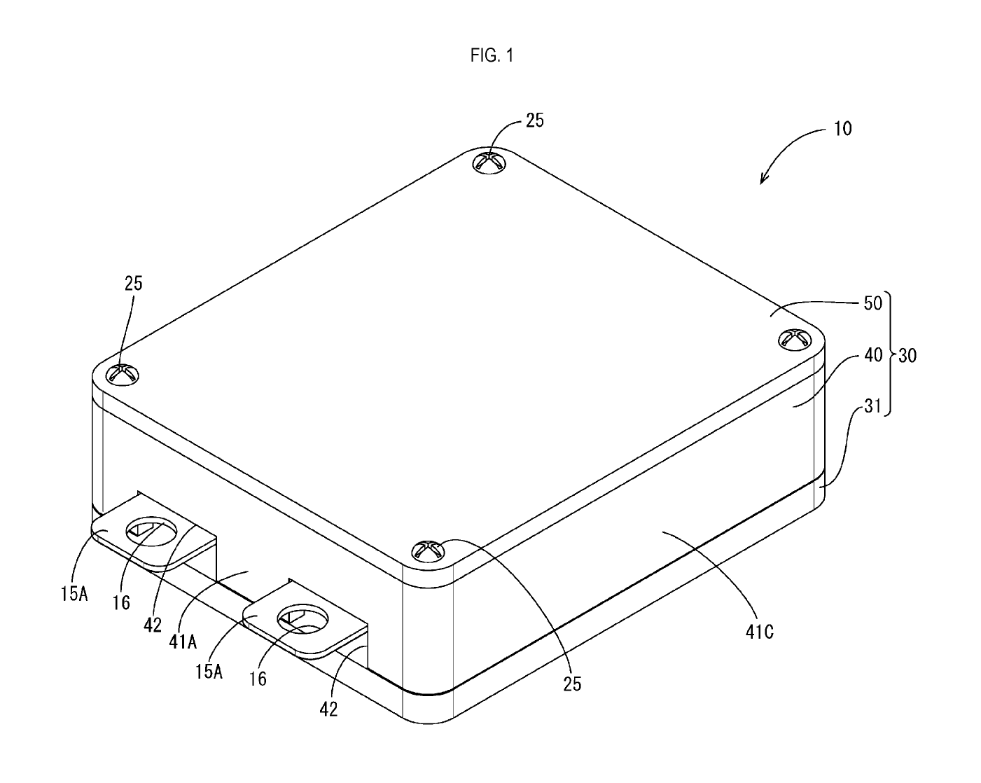

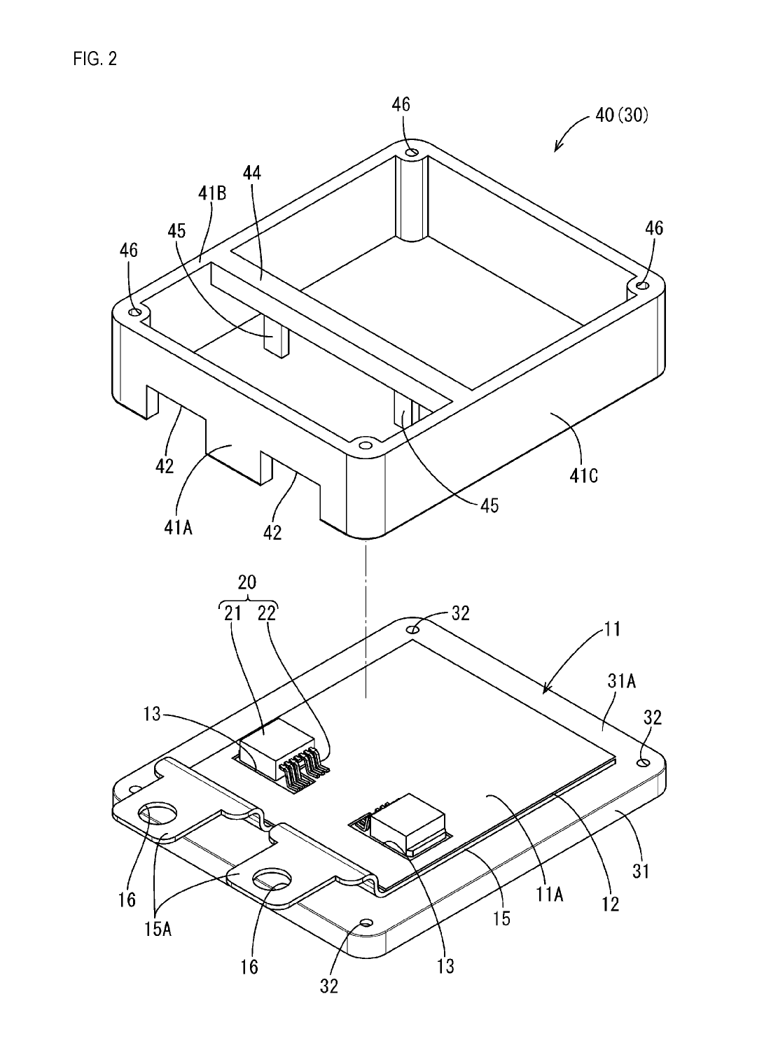

Hereinafter, an embodiment will be described with reference to FIGS. 1 to 4. An electrical junction box 10 according to this embodiment shown in FIG. 1 is, for example, a DC/DC converter that can be provided in vehicles such as electric vehicles and hybrid cars. In the description below, the upper side in FIGS. 1 and 2 is referred to as “upper side”, the lower side therein is referred to as “lower side”, the front left side therein is referred to as “front side”, and the rear right side therein is referred to as “rear side”.

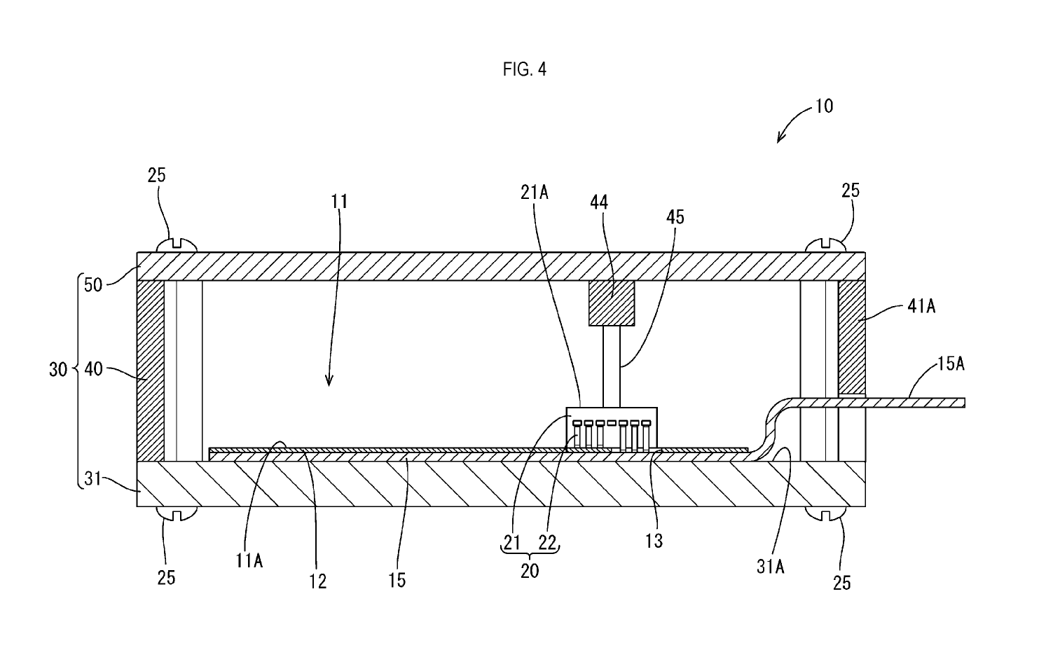

The electrical junction box 10 includes a circuit board 11 on which electronic components 20 such as transistors are mounted, and a case 30 in which the circuit board 11 is accommodated (see FIG. 4).

### Circuit Board 11

On the circuit board 11, an unshown printed circuit is formed through printed wiring and the electronic components 20 are arranged on a front face of an insulating substrate 12 (a mounting face 11A of the circuit board 11). A plurality of bus bars 15 are arranged in a predetermined pattern on its back face (the face opposite to the mounting face 11A).

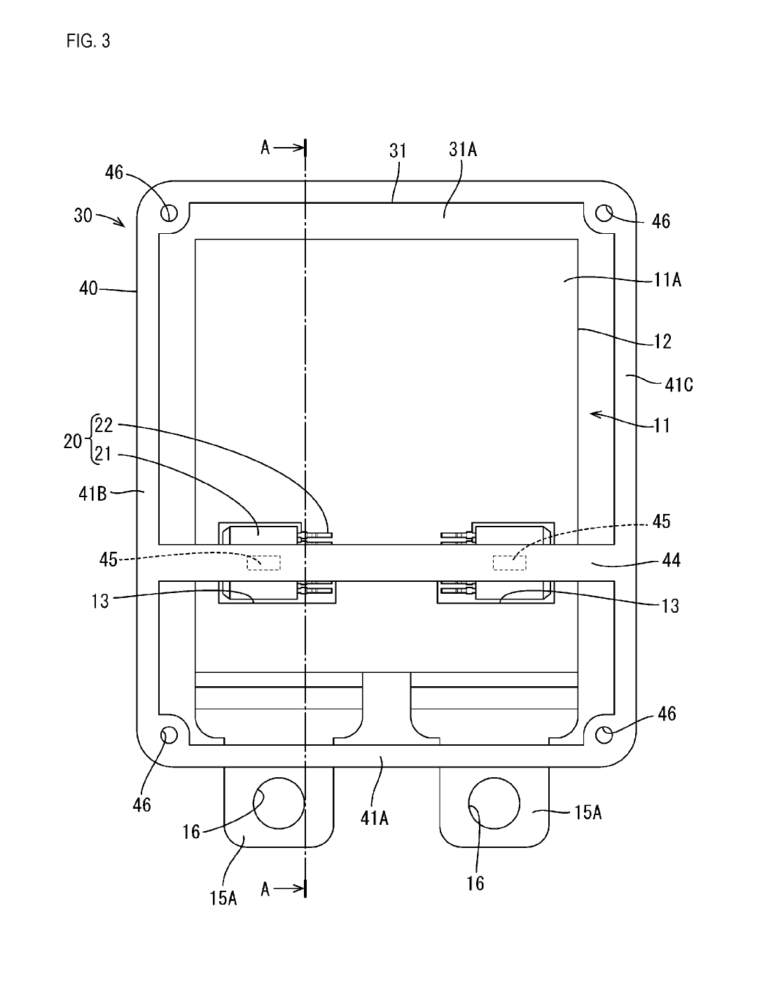

As shown in FIGS. 2 and 3, the circuit board 11 substantially has the shape of a rectangle in which a pair of openings 13 are provided at predetermined positions. The openings 13 are used to place main bodies 21 of the electronic components 20, and to connect connection terminals 22 (an example of a connecting portion) to the bus bars 15. The connection terminals 22 of the electronic components 20 are soldered to the surface of the bus bars 15 exposed from the openings 13.

Two external connection bus bars 15A that are to be connected to unshown external terminals project from the edge on the front side (the front left side in FIG. 2) of the circuit board 11, and their front ends are bent in a crank shape. These front ends have bolt holes 16 through which bolts (not shown) for establishing connection can pass.

### Case 30

The above-described circuit board 11 is accommodated in the case 30. The case 30 is constituted by a heat dissipation plate 31 (an example of a bonding case part) that is a rectangular flat plate and is arranged on a lower face (the face opposite to the mounting face 11A) side of the circuit board 11, a frame 40 (an example of a pressing case part and a frame member) that is substantially rectangular and surrounds the circuit board 11, and a cover 50 (an example of a pressing case part) that covers the circuit board 11 positioned on the heat dissipation plate 31 from the upper side of the frame 40.

The heat dissipation plate 31 is made of, for example, a metal material with excellent thermal conductivity, such as aluminum or aluminum alloy, and functions as a heat sink for dissipating heat generated by the circuit board 11.

The frame 40 is made of a synthetic resin, and one of its four side walls (a front side wall 41A on the front left side in FIG. 2) is cut out substantially in the shape of Us from the lower edge upward, forming a pair of cut outs 42 for guiding the above-described external connection bus bars 15A to the outside.

The four corners of the frame 40 protrude inward, forming protruding portions through which bolt holes 46 vertically extend and that can allow later-described bolts 25 to be screwed thereinto.

A pair of left and right side walls 41B and 41C of the frame 40 are provided with a bridge portion 44 that spans the pair of side walls 41B and 41C. The bridge portion 44 is in the shape of a rectangular column extending from the upper end of one of the pair of side walls 41B and 41C toward the other side wall 41C, 41B. The bridge portion 44 includes a portion facing the main bodies 21 of the electronic components 20 when the circuit board 11 is accommodated (positioned) at a predetermined position in the case 30 (see FIG. 3).

A pair of plate-like pressing pieces 45 (an example of a pressing portion) extend downward from the lower face of the bridge portion 44. The pressing pieces 45 are arranged at positions facing the main bodies 21 of the electronic components 20 when the circuit board 11 is accommodated (positioned) at a predetermined position in the case 30, and are set to have a length that allows the front ends thereof to press downward upper faces 21A of the main bodies 21 of the electronic components 20 (see FIG. 4).

The cover 50 is made of a synthetic resin, and is in the shape of a rectangular plate that covers the circuit board 11. When the cover 50 is laid over the frame 40, the case 30 is closed.

The portions of the above-described heat dissipation plate 31 and cover 50 that conform to the bolt holes 46 of the frame 40 when they are laid over the frame 40 are provided with bolt holes 32 that can allow the bolts 25 to be screwed thereinto (the bolt holes of the cover 50 are not shown).

### Method for Producing Electrical Junction Box 10

Next, a method for producing the electrical junction box 10 according to this embodiment will be described. First, a conductive circuit (not shown) is printed through printed wiring on a front face of the insulating substrate 12 (the mounting face 11A of the circuit board 11), and an adhesive sheet (not shown) is attached to its back face (the face opposite to the mounting face 11A) and the plurality of bus bars 15 are attached to the adhesive sheet in a predetermined pattern.

Next, the electronic components 20 are placed at predetermined positions on the front face of the insulating substrate 12 (the mounting face 11A of the circuit board 11), and are connected to a conductive circuit on the front face and the bus bars 15 on the back face through reflow soldering. In FIGS. 2 to 4, the electronic components 20 represent transistors, and the main bodies 21 of the electronic components 20 are placed on the bus bars 15 exposed from the openings 13 of the insulating substrate 12. Some of the plurality of connection terminals 22 extending from side faces of the main bodies 21 are connected to the bus bars 15 exposed from the openings 13 of the insulating substrate 12. Accordingly, a circuit board 11 on which the electronic components 20 are mounted is completed.

Next, an insulating adhesive (not shown) is applied to a necessary region (a region in which the circuit board 11 is to be arranged) on an upper face 31A of the heat dissipation plate 31 (an example of a bonding face of a bonding case part), and the circuit board 11 is placed at that predetermined position.

Then, the frame 40 is laid over the heat dissipation plate 31, the bolts 25 are screwed from the lower face side into the bolt holes 32 of the heat dissipation plate 31 and the bolt holes 46 of the frame 40, so that the frame 40 is fixed to the heat dissipation plate 31 (through the screwing).

In this state, the bridge portion 44 provided on the frame 40 is positioned above the main bodies 21 of the electronic components 20 (at a position facing the main bodies 21), and, when the bolts 25 are screwed, front ends (lower ends) of the pressing pieces 45 provided on the bridge portion 44 press the main bodies 21 toward the upper face 31A of the heat dissipation plate 31 (an example of a bonding face of a bonding case part).

Lastly, the cover 50 is laid over the frame 40, covering the circuit board 11, and the bolts 25 are screwed into the bolt holes (not shown) of the cover 50 and the bolt holes 46 of the frame 40, so that the cover 50 is fixed to the frame 40 (through the screwing). In this state, the lower face of the cover 50 is arranged so as to exactly conform to the upper face of the bridge portion 44, and thus the pressing pieces 45 more reliably press the main bodies 21 toward the upper face 31A of the heat dissipation plate 31. In this manner, the electrical junction box 10 is completed.

### Actions and Effects

With this electrical junction box 10 according to this embodiment, the pressing pieces 45 with which the frame 40 is provided press the main bodies 21 of the electronic components 20 toward the upper face 31A of the heat dissipation plate 31. That is to say, the circuit board 11 (the bus bars 15) is pressed toward the upper face 31A of the heat dissipation plate 31, and thus, even when an adhesive for fixing the heat dissipation plate 31 and the circuit board 11 has not been completely solidified during the production process, the circuit board 11 can be held in an immovable manner relative to the heat dissipation plate 31. That is to say, the procedure can advance to the next step or the product can be conveyed without waiting for an adhesive to be completely solidified, and thus the productivity is improved.

Furthermore, with this configuration, also after the adhesive is solidified, the pressing by the pressing pieces 45 continues, and thus a high adhesive force as in conventional cases where the circuit board 11 and the case 30 (the heat dissipation plate 31) are fixed to each other only with an adhesive is not required. That is to say, a relatively inexpensive general-purpose adhesive that is solidified at room temperature can be used instead of conventionally used highly adhesive thermosetting resins or the like, and thus the material cost can be kept low. Moreover, dedicated facilities, jigs for holding until an adhesive is solidified, and the like that are necessary in the case of using thermosetting resins are no more necessary, and thus the facility cost can be kept low, and the overall production cost can be significantly lowered.

Furthermore, the pressing pieces 45 and the frame 40 are integrally formed using part (the frame 40) of the case 30 for accommodating the circuit board 11, and the configuration can be made simple without increasing the number of parts.

Furthermore, since the frame 40 and the heat dissipation plate 31 are fixed through screws, the pressing pieces 45 can reliably press the main bodies 21 of the electronic components 20 toward the heat dissipation plate 31.

Moreover, since part of the case 30 is formed as the heat dissipation plate 31, the temperature of the electrical junction box 10 can be prevented from being high.

### Other Embodiments

The technology disclosed in this specification is not limited to the foregoing embodiment described above with reference to the drawings, and, for example, embodiments as described below are also embraced within the technical scope of the present invention.

In the foregoing embodiment, the pressing pieces 45 are integrally formed with the frame 40 of the case 30 by providing the bridge portion 44 on the frame 40, but a pressing portion that presses the main bodies 21 of the electronic components 20 toward the upper face 31A of the heat dissipation plate 31 may also be provided by installing a separate member into the electrical junction box 10.

The pressing portion is not limited to the plate-like pressing pieces 45, and may also have any shape such as a round bar or a rectangular column.

In the foregoing embodiment, the case 30 of the electrical junction box 10 is constituted by the heat dissipation plate 31, the frame 40, and the cover 50, but it is also possible that the case does not include the frame 40. In that case, it is preferable that the cover (pressing case part) is integrally provided with a pressing portion.

In the foregoing embodiment, the heat dissipation plate 31 and the frame 40 are fixed through screws, but the fixing method is not limited to that described in the embodiment, and, for example, the fixing method may also use an adhesive or an interlock means.

In the foregoing embodiment, the heat dissipation plate 31 is made of a metal so as to have the function of a heat sink, but may also be a bottom plate portion made of a synthetic resin.

In the foregoing embodiment, the external connection bus bars 15A are connected to external terminals via bolts, but the connection may also be made by attaching an external connector.

1. An electrical junction box comprising:
a circuit board having a mounting face on which an electronic component having a main body and a connecting portion is mounted; and
a case accommodating the circuit board,
wherein the case includes:
a bonding case part having a bonding face to which a face of the circuit board opposite to the mounting face is bonded; and
a pressing case part assembled to the bonding case part and having a pressing portion that presses the main body of the electronic component toward the bonding face,
the pressing case part includes a cover that covers the circuit board, and a frame member arranged between the cover and the bonding case part,
the frame member is provided with a bridge portion arranged at a position facing at least the main body of the electronic component when the circuit board is positioned on the bonding case part, and
the pressing portion projects from the bridge portion toward the circuit board.

2. (canceled)

3. The electrical junction box according to claim 1, wherein the pressing case part and the bonding case part are fixed through screws.

4. The electrical junction box according to claim 1, wherein the bonding case part is made of metal.

5. The electrical junction box according to claim 1, wherein a bus bar is arranged on a face of the circuit board opposite to the mounting face.

6. The electrical junction box according to claim 3, wherein the bonding case part is made of metal.

7. The electrical junction box according to claim 3, wherein a bus bar is arranged on a face of the circuit board opposite to the mounting face.

8. The electrical junction box according to claim 4, wherein a bus bar is arranged on a face of the circuit board opposite to the mounting face.
